(19) United States
(12) Patent Application Publication
(10) Pub. No.: US 2016/0247690 A1
(43) Pub. Date: Aug. 25, 2016

(54) ETCHING DEVICE, ETCHING METHOD, AND SUBSTRATE-MOUNTING MECHANISM

(71) Applicant: TOKYO ELECTRON LIMITED, Minato-ku, Tokyo (JP)

(72) Inventors: Hiroyuki TAKAHASHI, Nirasaki-shi, Yamanashi (JP); Yoshihiko NAKAMURA, Nirasaki-shi, Yamanashi (JP); Shigeki TOZAWA, Tokyo (JP); Yusuke NAKAMURA, Nirasaki-shi, Yamanashi (JP); Susumu HOSAKA, Nirasaki-shi, Yamanashi (JP)

(21) Appl. No.: 15/027,740

(22) PCT Filed: Sep. 26, 2014
(86) PCT No.: PCT/JP2014/075623

§ 371 Date: Apr. 7, 2016

(30) Foreign Application Priority Data
Oct. 17, 2013 (JP) 2013-216557

(51) Int. Cl. H01L 21/311; H01L 21/67; H01L 21/687; H01L 21/02

(52) U.S. Cl. CPC H01L 21/31116; H01L 21/02164; H01L 21/67069; H01L 21/67109; H01L 21/68757

(57) ABSTRACT

An etching device for etching a silicon-containing film formed on a substrate W is includes: a chamber; a substrate mounting mechanism provided in the chamber; a gas supply mechanism configured to supply an etching gas composed of fluorine, hydrogen, and nitrogen into the chamber; and an exhaust mechanism. The substrate mounting mechanism includes: a mounting table; temperature adjusting mechanisms configured to adjust a temperature of a mounting surface of the mounting table to 50 degrees C. or less; and a heating member configured to heat at least a portion of surfaces other than the mounting surface in the mounting table to 60 to 100 degrees C. A resin coating layer is formed at least on the mounting surface of the mounting table.

### TECHNICAL FIELD

The present disclosure relates to an etching device which etches a film formed of a predetermined material formed on a substrate, an etching method, and a substrate mounting mechanism.

### BACKGROUND

In recent years, in a semiconductor device manufacturing process, a technique called chemical oxide removal (COR) draws attentions as an alternative fine etching method for dry etching or wet etching.

As the COR treatment known in the related art, there is an etching treatment in which a hydrogen fluoride (HF) gas and an ammonia (NH₃) gas are adsorbed to a silicon oxide film (SiO₂ film) residing on a surface of a semiconductor wafer as a target object such that these gases react with the silicon oxide film to etch the silicon oxide film, and by-products mainly composed of ammonium fluorosilicate ((NH₄)₂SiF₆; AFS) generated during the reaction are heated in a subsequent process to be removed through sublimation (for example, see Patent Documents 1 and 2).

As disclosed in Patent Document 2, such a COR treatment is used in a processing system which includes a COR treatment device and a post heating treatment (PHT) device. The COR treatment device mounts a semiconductor wafer having a silicon oxide film formed thereon on a mounting table within a chamber, supplies an HF gas and an NH₃ gas into the chamber such that these gases react with the silicon oxide film, thus etching the silicon oxide film. The post heating treatment (PHT) device performs a PHT treatment with respect to the semiconductor wafer to which by-products mainly composed of AFS generated by the reaction adhere, within the chamber.

### PRIOR ART DOCUMENTS

### Patent Documents

Patent Document 1: Japanese laid-open publication No. 2005-39185

Patent Document 2: Japanese laid-open publication No. 2008-160000

However, upon etching the silicon oxide film using the HF gas and the NH₃ gas, such a COR treatment apparatus tends to suffer from a problem of reduction in etching rate with an increase in the number of wafers when a plurality of wafers is continuously processed at a low temperature of 50 degrees C. or less. Such tendency occurs not only when etching the silicon oxide film using the HF gas and the NH₃ gas, but also when etching a silicon-containing film using an etching gas consisting of fluorine, hydrogen and nitrogen to generate an ammonium fluorosilicate as an etching by-product.

### SUMMARY

Some embodiments of the present disclosure provide an etching device and an etching method, which are capable of suppressing a reduction in etching rate when continuously performing an etching treatment with respect to a plurality of substrates each having a silicon-containing film formed thereon, using an etching gas consisting of fluorine, hydrogen and nitrogen at a low temperature of 50 degrees C. or less, and a substrate mounting mechanism used therefor.

According to one embodiment of the present disclosure, an etching device for etching a silicon-containing film formed on a substrate using an etching gas containing fluorine, hydrogen and nitrogen to generate an ammonium fluorosilicate as a by-product includes: a chamber configured to accommodate the substrate having the silicon-containing film formed thereon; a substrate mounting mechanism disposed within the chamber; a gas supply mechanism configured to supply the etching gas containing fluorine, hydrogen and nitrogen into the chamber; and an exhaust mechanism configured to exhaust an interior of the chamber, wherein the substrate mounting mechanism includes: a mounting table having a mounting surface on which the substrate is mounted, a temperature adjustment mechanism configured to adjust a temperature of the mounting surface of the mounting table to 50 degrees C. or less; and a heating member configured to heat at least a portion of surfaces other than the mounting surface in the mounting table to a temperature of 60 to 100 degrees C., and wherein a coating layer of a resin material is formed at least on the mounting surface of the mounting table.

In the etching device according to this embodiment, an HF gas and an NH₃ gas may be used as the etching gas, and a silicon oxide film may be used as the silicon-containing film.

In some embodiments, the coating layer may have a contact angle of 75 degrees or more and a surface roughness Ra of 1.9 μm or less. The coating layer may be formed of an FCH-based resin consisting of F, C and H or a CH-based resin consisting of C and H.

In some embodiments, the etching device may further include a heater configured to heat a wall portion of the chamber. The heating member may be configured to heat the surfaces other than the mounting surface in the mounting table using heat that is radiated from the wall portion of the chamber heated by the heater.

In some embodiments, a mechanism configured to adjust the temperature of the mounting surface by circulating a temperature adjustment medium through the mounting table may be used as the temperature adjustment mechanism. A gap may be formed between the mounting table and the heating member to act as an exhaust channel.

According to another embodiment of the present disclosure, an etching method for etching a silicon-containing film formed on a substrate using an etching gas containing fluorine, hydrogen and nitrogen to generate an ammonium fluorosilicate as a by-product, includes: installing a mounting table within a chamber, the mounting table including a coating layer of a resin material formed at least on a mounting surface thereof on which the substrate is mounted; mounting the substrate having the silicon-containing film formed thereon on the mounting surface of the mounting table; adjusting a temperature of the mounting surface of the mounting table to 50 degrees C. or less; heating at least a portion of surfaces other than the mounting surface in the mounting table to a temperature of 60 to 100 degrees C.; and supplying the etching gas containing fluorine, hydrogen and nitrogen into the chamber to etch the silicon-containing film.

In the etching method, an HF gas and an NH₃ gas may be used as the etching gas, and a silicon oxide film may be used as the silicon-containing film. In this case, a partial pressure of the HF gas at the time of etching falls within a range from 10 to 80 mTorr, which increases an effect.

According to yet another embodiment of the present disclosure, a substrate mounting mechanism for mounting a substrate having a silicon-containing film formed thereon within an etching device which etches the silicon-containing film formed on the substrate using an etching gas containing fluorine, hydrogen and nitrogen to generate an ammonium fluorosilicate as a by-product includes: a mounting table having a mounting surface on which the substrate is mounted; a temperature adjustment mechanism configured to adjust a temperature of the mounting surface of the mounting table to 50 degrees C. or less; and a heating member configured to heat at least a portion of surfaces other than the mounting surface in the mounting table to a temperature of 60 to 100 degrees C., wherein a coating layer of a resin material is formed at least on the mounting surface of the mounting table.

According to the present disclosure, a coating layer formed on a mounting surface adjusted to a low temperature of 50 degrees C. is formed of a resin material having a water repellency and a surface smoothness, which makes it difficult to generate deposits thereon without having to heat. Further, surfaces other than the mounting surface in the mounting table are heated to 60 to 100 degrees C. such that adhesion of deposits to the mounting surface can be suppressed and also the adhered deposits can be sublimated. Accordingly, it is possible to suppress a reduction in etching rate due to deposits even when continuously etching a plurality of substrates.

### BRIEF DESCRIPTION OF THE DRAWINGS

FIG. 1 is a schematic view of an exemplary processing system provided with an etching device according to one embodiment of the present disclosure.

FIG. 2 is a sectional view of a heating treatment device provided in the processing system of FIG. 1.

FIG. 3 is a sectional view of the etching device according to the embodiment of the present disclosure, which is provided in the processing system of FIG. 1.

FIG. 4 is a sectional view illustrating a main part of a substrate mounting mechanism in the etching device of FIG. 3.

FIG. 5 is a view illustrating a border line between a “deposit-rich” region and a “deposit-less” region, with a temperature as a horizontal axis and a partial pressure of HF gas as a vertical axis.

FIG. 6A is a view depicting a relationship between the number of cycles (the number of wafers), an etching rate and a deviation thereof when continuously etching a plurality of wafers using HF gas and NH₃ gas, in cases where a coating layer is formed on a surface of a mounting table and the coating layer is not formed on the surface.

FIG. 6B is a view depicting a relationship between the number of cycles (the number of wafers), an etching rate and an APC angle when continuously etching the plurality of wafers using HF gas and NH₃ gas, in cases where a coating layer is formed on a surface of a mounting table and the coating layer not formed on the surface.

FIG. 7 is a view depicting a first wafer etching rate obtained when an etching treatment is initially performed, a second wafer etching rate obtained after the etching treatment was continuously performed using HF gas and NH₃ gas, a third wafer etching rate obtained after a baking treatment was performed at 80 to 100 degrees C., and a fourth wafer etching rate obtained after the continuous etching treatment was further performed, in a state where a temperature of a mounting surface of a mounting table not having a coating layer is maintained at 10 to 40 degrees C.

FIG. 8 is a view depicting RGA analysis of sublimated materials when a baking treatment was performed at 80 degrees C., after deposits are generated on the mounting table by an etching treatment using HF gas and NH₃ gas.

FIG. 9A is a view depicting results obtained by measuring an amount of deposits through a weight measurement, after an etching treatment with HF gas and NH₃ gas, using a mounting table formed of aluminum alone, a mounting table formed of aluminum whose surface is anodized, a mounting table having a CH-based coating layer formed thereon, and a mounting table having a CHF-based coating layer formed thereon.

FIG. 9B is a view depicting results obtained by measuring an amount of deposits through an ion chromatography, after an etching treatment with HF gas and NH₃ gas, using a mounting table formed of aluminum alone, a mounting table formed of aluminum whose surface is anodized, a mounting table having a CH-based coating layer formed thereon, and a mounting table having a CHF-based coating layer formed thereon.

### DETAILED DESCRIPTION

The inventors of the present disclosure investigated the reason for deterioration in etching rate when continuously etching of a silicon-containing film formed on a substrate at a low temperature of 50 degrees C. or less using an etching gas containing fluorine, hydrogen and nitrogen. As a result, the inventors of the present disclosure have found that, when such a continuous etching is carried out at a low temperature of 50 degrees C. or less, ammonium fluorosilicate as a by-product caused by adsorption or reaction of the etching gas onto a mounting table adheres to the mounting table, which generates deposits, which in turn gathers like a snowball as the number of processed substrates increases, thereby causing a decrease in the amount of gas consumed on each substrate over time.

Based on such findings, the inventors of the present disclosure have found that deterioration of the etching rate can be suppressed by suppressing such deposits and thus developed the present disclosure.

Hereinafter, some embodiments of the present disclosure will be described with reference to the accompanying drawings.

The following description will be given of embodiments wherein a semiconductor wafer (hereinafter, simply referred to as a “wafer”) having a silicon oxide film formed on a surface thereof is used as a target substrate and the silicon oxide film formed on the surface of the wafer is subjected to a non-plasma dry etching using HF gas and NH₃ gas.

<Configuration of Processing System>

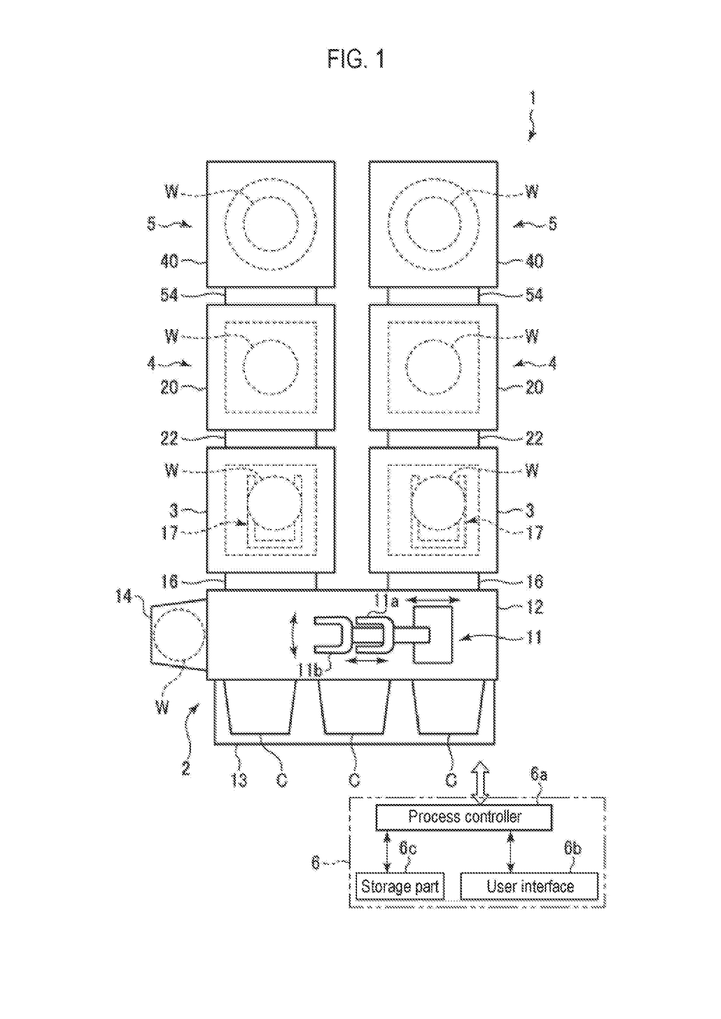

FIG. 1 is a schematic view showing an example of a processing system provided with an etching device according to one embodiment of the present disclosure. The processing system 1 includes a loading/unloading part 2 through which a wafer W as a target substrate is transferred, two load lock (L/L) chambers 3 disposed near the loading/unloading part 2, heating devices 4 disposed near each of the load lock chambers 3 and configured to perform a post heating treatment (PHT) with respect to the wafer W, etching devices 5 disposed near each of the heating devices 4 and configured to perform a COR treatment as etching treatment with respect to the wafer W, and a control part 6. The load lock chambers 3, the heating devices 4, and the etching devices 5 are arranged in a line in this order, respectively.

The loading/unloading part 2 includes a transfer chamber (L/M) 12 provided with a first wafer transfer mechanism 11 configured to transfer the wafer W. The first wafer transfer mechanism 11 includes two transfer arms 11a and 11b configured to hold the wafer Win a substantially horizontal posture. A mounting table 13 is disposed at one side of the transfer chamber 12 in a longitudinal direction of the transfer chamber 12. For example, three carriers C, each of which is capable of accommodating a plurality of wafers W, are connected to the mounting table 13. Furthermore, an orientor 14 configured to perform position alignment of the wafer W by rotating the wafer W and finding an eccentric amount thereof is installed adjacent to the transfer chamber 12.

In the loading/unloading part 2, the wafer W is held by one of the transfer arms 11a, and 11b and is moved linearly within a substantially horizontal plane or moved up and down by the operation of the first wafer transfer mechanism 11, thereby being transferred to a desired position. Further, the wafer W is loaded or unloaded with respect to the carriers C mounted on the mounting table 13, the orientor 14 and the load lock chambers 3, as the transfer arms 11a and 11b move toward or away from the respective carrier C, the orientor 14 and the respective load lock chambers 3.

Each of the load lock chambers 3 is connected to the transfer chamber 12 with a gate valve 16 interposed between each of the load lock chambers 3 and the transfer chamber 12. A second wafer transfer mechanism 17 for transferring the wafer W is installed within each of the load lock chambers 3. Each of the load lock chambers 3 is configured so that it can be evacuated to a predetermined degree of vacuum.

The second wafer transfer mechanism 17 has an articulated arm structure and includes a pick configured to hold the wafer W in a substantially horizontal posture. In the second wafer transfer mechanism 17, the pick is positioned within each of the load lock chambers 3 when an articulated arm is retracted. The pick can reach a respective one of the heating devices 4 as the articulated arm is extended and can reach a respective one of the etching devices 5 as the articulated arm is further extended. Thus, the second wafer transfer mechanism 17 can transfer the wafer W between the load lock chamber 3, the heating device 4 and the etching device 5.

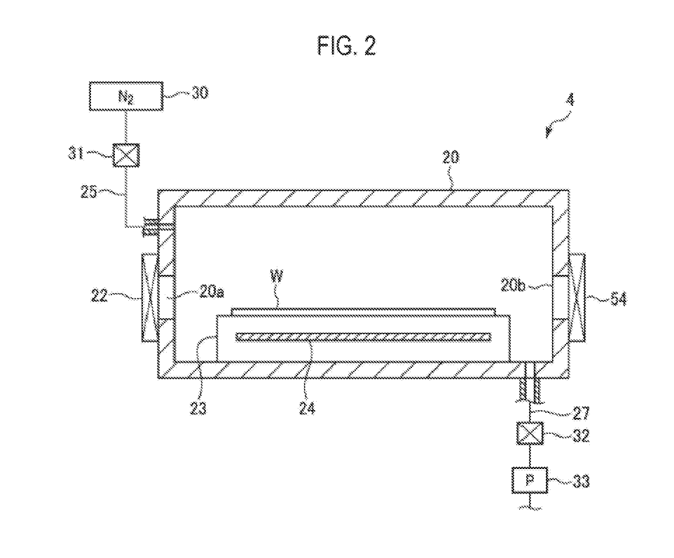

The following description is given of the heating device 4. FIG. 2 is a sectional view of the heating device 4. Each of the heating devices 4 includes a vacuum-evacuable chamber 20 and a mounting table 23 configured to mount the wafer W within the chamber 20. A heater 24 is embedded in the mounting table 23. After being subjected to an etching treatment, the wafer W is heated by the heater 24, thereby vaporizing and removing etching residue which exists on the wafer W. A loading/unloading gate 20a through which the wafer W is transferred between the heating device 4 and the load lock chamber 3 is formed in a sidewall of the chamber 20 adjoining the load lock chamber 3. The loading/unloading gate 20a is opened and closed by a gate valve 22. In addition, a loading/unloading gate 20b through which the wafer W is transferred between the heating device 4 and the etching device 5 is formed in the sidewall of the chamber 20 adjoining the etching device 5. The loading/unloading gate 20b is opened and closed by a gate valve 54. A gas supply path 25 is connected to an upper portion of the sidewall of the chamber 20. The gas supply path 25 is connected to an N₂ gas supply source 30. An exhaust path 27 is connected to a bottom wall of the chamber 20. The exhaust path 27 is connected to a vacuum pump 33. A flow rate adjusting valve 31 is installed in the gas supply path 25. A pressure adjusting valve 32 is installed in the exhaust path 27. By controlling the flow rate adjusting valve 31 and the pressure adjusting valve 32, the interior of the chamber 20 is kept in a N₂ gas atmosphere having a predetermined pressure. In this state, a heating treatment is performed. Instead of the N₂ gas, another inert gas may be used.

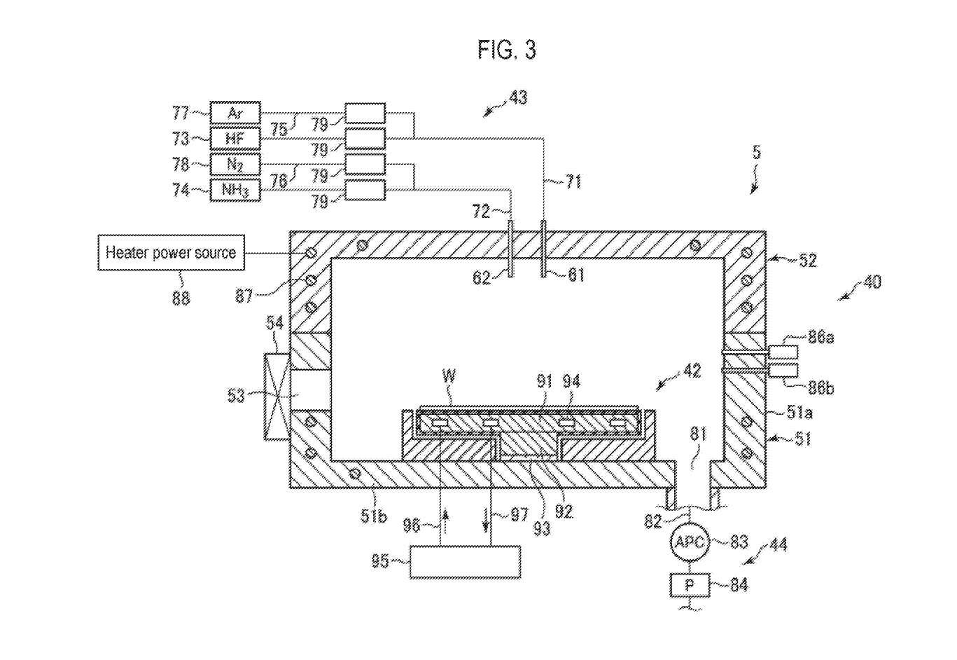

Next, the etching device 5 according to this embodiment of the present disclosure will be described. FIG. 3 is a sectional view of the etching device 5 and FIG. 4 is an enlarged view of a main part of the etching device 5. The etching device 5 includes a chamber 40 having a closed structure, a substrate mounting mechanism 42 disposed within the chamber 40 and configured to mount the wafer W as a substrate thereon in a substantially horizontal state, a gas supply mechanism 43 configured to supply an etching gas to the chamber 40, and an exhaust mechanism 44 configured to exhaust the interior of the chamber 40.

The chamber 40 includes a chamber body 51 and a lid 52. The chamber body 51 has a substantially cylindrical sidewall 51a and a bottom 51b. An upper side of the chamber body 51 is opened and is closed by the lid 52. The sidewall 51a and the lid 52 are sealed by a sealing member (not shown) to maintain air-tightness of the chamber 40. A first gas supply nozzle 61 and a second gas supply nozzle 62 are inserted into the chamber 40 through a ceiling wall of the lid 52.

The sidewall 51a is formed with a transfer port 53 through which the wafer W is loaded into and unloaded from the chamber 20 of the heating device 4. The transfer port 53 can be opened or closed by a gate valve 54.

The gas supply mechanism 43 includes a first gas supply pipe 71 and a second gas supply pipe 72 connected respectively to the first gas supply nozzle 61 and the second gas supply nozzle 62, and an HF gas supply source 73 and an NH₃ gas supply source 74 connected respectively to the first gas supply pipe 71 and the second gas supply pipe 72. Furthermore, a third gas supply pipe 75 is connected to the first gas supply pipe 71 and a fourth gas supply pipe 76 is connected to the second gas supply pipe 72. The third gas supply pipe 75 and the fourth gas supply pipe 76 are connected to an Ar gas supply source 77 and an N₂ gas supply source 78, respectively. A flow rate control part 79 configured to control an opening/closing operation of a flow channel and a flow rate thereof is installed in each of the first to fourth gas supply pipes 71, 72, 75, 76. The flow rate control part 79 is composed of, for example, a switching valve and a mass flow controller.

Furthermore, an HF gas and an Ar gas are discharged into the chamber 40 through the first gas supply pipe 71 and the first gas supply nozzle 61, and an NH₃ gas and an N₂ gas are discharged into the chamber 40 through the second gas supply pipe 72 and the second gas supply nozzle 62. In some embodiments, these gases may be discharged into the chamber 40 in a shower shape through a shower plate.

Among these gases, the HF gas and the NH₃ gas are used as an etching gas and are mixed with each other within the chamber 40. The Ar gas and the N₂ gas are used as a dilution gas. The HF gas and the NH₃ gas as the etching gas, and the Ar gas and the N₂ gas as the dilution gas are introduced into the chamber 40 at a predetermined flow rate and the chamber 40 is maintained at a predetermined pressure. Under this situation, the HF gas and the NH₃ gas react with an oxide film (SiO₂) formed on the surface of the wafer W, thus generating an ammonium fluorosilicate (AFS) and the like as by-products.

The dilution gas may be selected from among the Ar gas, the N₂ gas, other inert gases, and a combination thereof.

The exhaust mechanism 44 includes an exhaust pipe 82 which is connected to an exhaust port 81 formed in the bottom 5 lb of the chamber 40, an automatic pressure control valve (APC) 83 disposed in the exhaust pipe 82 to control an internal pressure of the chamber 40, and a vacuum pump 84 configured to exhaust the interior of the chamber 40.

Two capacitance manometers 86a and 86b are installed to be inserted into the chamber 40 through the sidewall of the chamber 40 so as to measure the internal pressure of the chamber 40. The capacitance manometer 86a is used to measure a high pressure while the capacitance manometer 86b is used to measure a low pressure.

A heater 87 is embedded in the wall portion of the chamber 40 and generates heat by power provided from a heater power supply 88. Thus, an inner wall of the chamber 40 is heated. The control part 6 controls a temperature of the inner wall of the chamber 40 to be in a range of, for example, 60 to 100 degrees C., based on information provided from a temperature sensor (not shown).

As shown in FIG. 4, the substrate mounting mechanism 42 includes a mounting table 91 having a mounting surface on which the wafer W as a substrate is mounted. The mounting table 91 has a substantially circular shape when viewed for the top, and is supported by a support member 92 which is installed upright on the bottom 51b of the chamber 40 through a heat insulating member 93. A temperature adjustment medium channel 94 through which a temperature adjustment medium (for example, water) circulates is formed within the mounting table 91. The temperature adjustment medium circulates through the temperature adjustment medium channel 94 via temperature adjustment medium pipes 96 and 97 by a temperature adjustment medium circulation mechanism 95 such that the mounting surface of the mounting table 91 is controlled to a predetermined temperature of 50 degrees C. or less.

A body of the mounting table 91 is formed of a metal having good thermal conductivity, for example, aluminum. A coating layer 98 of resin material is formed on a surface of the body, except for a region where the body is in contact with the support member 92. Since the coating layer 98 is formed of the resin material, the coating layer 98 exhibits water repellency and good surface smoothness. Accordingly, the coating layer 98 makes it difficult to generate deposits due to the by-product caused by adsorption gas or etching reaction. The resin material for the coating layer 98 may have a contact angle of 75 degrees or more and a surface roughness Ra of 1.9 μm or less. Examples of the resin material may include an FCH-based resin consisting of F, C and H, for example, WIN KOTE® water repellency specification, and a CH-based resin consisting of C and H, for example, WIN KOTE® standard specification. In some embodiments, the coating layer 98 has a thickness of 5 μ to 20 μm. The coating layer 98 may be formed in any region of the mounting table 91 so long as it is formed at least on the mounting surface of the mounting table 91.

The substrate mounting mechanism 42 further includes a heating block 99 configured to heat surfaces other than the mounting surface of the mounting table 91, i.e., a lateral surface and a rear surface of the mounting table 91. The heating block 99 has a recess 99a corresponding to the mounting table 91 and the support member 92, and generally has a cylindrical shape. The heating block 99 is directly in contact with the bottom 51b of the chamber 40. The heating block 99 is formed of a metal having good thermal conductivity, for example, aluminum, and is configured to be heated to the same temperature as the wall of the chamber 40. On the other hand, since the support member 92 is thermally insulated from the bottom of the chamber 40 by the heat insulating member 93, the temperature of the mounting surface of the mounting table 91 can be controlled by the temperature adjustment medium.

A gap 101 is formed between the mounting table 91 and the heating block 99 and between the support member 92 and the heating block 99. The gap 101 is connected to the exhaust pipe 82 through an internal space of the chamber 40. Accordingly, the gap 101 acts as an exhaust channel.

In some embodiments, components other than the mounting table 91 and the heating block 99, for example, the chamber 40, may also be formed of aluminum. In the structure wherein the chamber 40 is formed of aluminum, a pure aluminum material may be used as the aluminum and an inner surface of the chamber 40 may be subjected to anodizing. In some embodiments, the region heated by the heating block 99 is not limited to the entire lateral surface and the entire rear surface of the mounting table 91, and may be a portion of the surfaces, for example, only the rear surface.

The control part 6 includes a process controller 6a equipped with a microprocessor (computer) configured to control each component of the processing system 1. The process controller 6a is connected to a user interface 6b including a keyboard that enables an operator to input commands for managing the processing system 1, a display and the like for visually displaying an operation state of the processing system 1. Furthermore, the process controller 6a is connected to a storage part 6c, which stores a control program for implementing various processes performed by the processing system 1, for example, a supply operation of a processing gas to the etching device 5, an exhaust operation of the chamber, and the like, under control of the process controller, process recipes, that is, control programs for controlling respective components of the processing system 1 to perform a predetermined process according to process conditions, or various databases. The recipes are stored in a suitable storage medium (not shown) in the storage part 6c. In some embodiments, as needed, a certain recipe is read from the storage part 6c and implemented by the process controller 6a such that a desired process can be carried out in the processing system 1 under control of the process controller 6a.

<Process Operation of Processing System>

Next, a process operation of the processing system 1 configured as above will be described.

First, a plurality of wafers W each having a silicon oxide film as an etching object formed on a surface thereof, while being received in the carrier C, is loaded into the processing system 1. In the processing system 1, the gate valve 16 of an atmosphere side is opened and one sheet of the wafer W is transferred from the respective carrier C of the loading/unloading part 2 into the respective load lock chamber 3 by one of the transfer arms 11a and 11b of the first wafer transfer mechanism 11, and subsequently, delivered to the peak of the second wafer transfer mechanism 17 within the load lock chamber 3.

Thereafter, the gate valve 16 of the atmosphere side is closed and the load lock chamber 3 is vacuum-exhausted. Subsequently, the gate valve 54 is opened and the peak is extended into the chamber 40 of the respective etching device 5 such that the wafer W is mounted on the mounting table 91 of the substrate mounting mechanism 42.

Thereafter, the peak is withdrawn into the respective load lock chamber 3 and the gate valve 54 is closed such that the chamber 40 is in a sealed state. Under this situation, the etching device 5 performs the etching treatment with respect to the silicon oxide film formed on the surface of the wafer W.

At this time, the wall portion of the chamber 40 of the etching device 5 is heated to 60 to 100 degrees C. by the heater 87. Furthermore, the temperature adjustment medium (for example, water) circulates through the temperature adjustment medium channel 94 by the temperature adjustment medium circulation mechanism 95 such that the mounting surface of the mounting table 91 is controlled to be heated to a predetermined temperature of 50 degrees C. or less, whereby the temperature of the wafer W is controlled to the predetermined temperature.

In this state, the HF gas and the Ar gas are discharged from the gas supply mechanism 43 into the chamber 40 through the first gas supply pipe 71 and the first gas supply nozzle 61, while the NH₃ gas and the N₂ gas are discharged into the chamber 40 through the second gas supply pipe 72 and the second gas supply nozzle 62. Here, one of the Ar gas and the N₂ gas may be used as the dilution gas.

In this way, as the HF gas and the NH3 gas are supplied into the chamber 40, the silicon oxide film formed on the surface of the wafer W chemically reacts with molecules of the hydrogen fluoride gas and the ammonia gas, whereby the silicon oxide film is etched. At this time, by-products mainly composed of ammonium fluorosilicate (AFS) remain on the surface of the wafer W.

After completion of such etching treatment, the gate valves 22 and 54 are opened and the peak of the second wafer transfer mechanism 17 picks up the wafer W which has been subjected to the etching treatment and mounted on the mounting table 91 of the etching device 5, transfers the same into the chamber 20 of the heating device 4 to mount on the mounting table 23. Then, the peak is returned into the load lock chamber 3 and the gate valves 22 and 54 are closed. Under this situation, the N₂ gas is introduced into the chamber 20 and the wafer W mounted on the mounting table 23 is heated by the heater 24. As a result, the by-products mainly composed of ammonium fluorosilicate generated by the etching treatment are sublimated and removed by heating.

In this way, since the etching treatment is followed by the heating treatment, the silicon oxide film on the surface of the wafer W can be removed under a dry atmosphere without generating water marks and the like. Further, since the etching treatment is carried out in a plasma-free manner, it is possible to reduce damage. Furthermore, since such etching treatment is not carried out after a predetermined period of time, over-etching can be prevented, thereby enabling omission of management of an end point.

After completion of the heating treatment by the heating device 4, the gate valve 22 is opened and the peak of the second wafer transfer mechanism 17 picks up the wafer W mounted on the mounting table 23, which has been subjected to the heating treatment, and transfers the same into the load lock chamber 3. Subsequently, the wafer W is returned to the respective carrier C by one of the transfer arms 11a and 11b of the first wafer transfer mechanism 11. In this way, a process for one sheet of the wafer is completed. Such a process is repeated with respect to the plurality of wafers W.

However, it is found that, as in this embodiment, when the etching treatment is continuously performed with respect to the plurality of wafers W at a low temperature of 50 degrees C. or less using the HF gas and the NH₃ gas in the etching device 5, the conventional device has a problem of reduction in an etching amount (etching rate) of the wafer. As a result of investigation as to the reason for this problem, the inventors of the present disclosure found that, since the mounting table for mounting the wafer thereon is maintained at a low temperature of 50 degrees C. or less, by-products generated by adsorption and reaction of the etching gas to the mounting table adhere to the mounting table to generate deposits, which in turn gather like a snowball as the number of processed wafers increases, thereby causing a decrease in the amount of gas consumed on each wafer over time. Moreover, it was found that the amount of deposits adhered to the mounting table is affected not only by temperature, but also by a partial pressure of the HF gas.

Accordingly, suppressing the generation of the deposits on the mounting table 91 is effective in suppressing a reduction in the etching rate when the plurality of wafers is continuously processed.

Although it is desirable that the mounting table 91 is heated like the wall of the chamber 40 in order to suppress the generation of deposits on the mounting table 91, since the mounting surface of the mounting table 91 is adjusted to the temperature of 50 degrees C. or less, it is difficult to heat the mounting table 91. Accordingly, in this embodiment, the coating layer 98 of the resin material is formed on the surface (at least the mounting surface) of the mounting table 91, thereby making it difficult to generate deposits. That is to say, since the coating layer 98 is formed of the resin material, the coating layer 98 has water repellency and high surface smoothness, thereby making it difficult to generate deposits on the mounting table without having to heat. In order to make it more difficult to generate deposits, as described above, the resin material for the coating layer 98 may have a contact angle of 75 degrees and a surface roughness Ra of 1.9 μm or less. The FCH-based resin consisting of F, C and H or the CH-based resin consisting of C and H may be suitably used as the resin material.

On the other hand, since the lateral surface and the rear surface of the mounting table 91 other than the mounting surface thereof is less affected by the temperature adjustment of the wafer and can be heated, the lateral surface and the rear surface of the mounting table 91 are heated like the wall portion of the chamber 40 to 60 to 100 degrees C. by the heating block 99, thereby suppressing the generation of deposits while enabling sublimation of the deposits even in the case where the deposits are generated thereon.

As described above, the coating layer 98 is formed on the surface of the mounting table 91, and the lateral and rear surfaces of the mounting table 91 are heated by the heating block 99 so that the generation of deposits is suppressed. Thus, it is possible to suppress a reduction in etching rate of each of the wafers when continuously processing the wafers.

Furthermore, since the heating block 99 is directly in contact with the wall portion of the chamber 40 which is heated by the heater 87 and thus receives heat from the wall portion, it is possible to heat the lateral surface and the rear surface of the mounting table 91 without using additional heating means. In some embodiments, the heating block 99 may be insulated from the wall portion of the chamber 40 and may act as an independent heating part. In some embodiments, the heating block 99 may be configured to heat the entire surface other than the mounting surface of the mounting table 91, i.e., both the lateral and the rear surfaces of the mounting table 91. Alternatively, the heating block 99 may be configured to heat a portion of the lateral and rear surfaces, for example, only the rear surface.

Furthermore, since the gap 101 formed between the mounting table 91 and the heating block 99 and between the support member 92 and the heating block 99 acts as the exhaust channel, it is possible to discharge the deposits together with an exhaust stream flowing through the gap 101 even in the case where the deposits are generated on the lateral surface or the rear surface of the mounting table 91.

While in this embodiment, the coating layer 98 has been described to be formed on the lateral and rear surfaces of the mounting table 91 to suppress the adhesion of deposits to the mounting table 91, since the lateral and rear surfaces of the mounting table 91 is heated by the heating block 99 to suppress the generation of deposits, the coating layer 98 may be omitted.

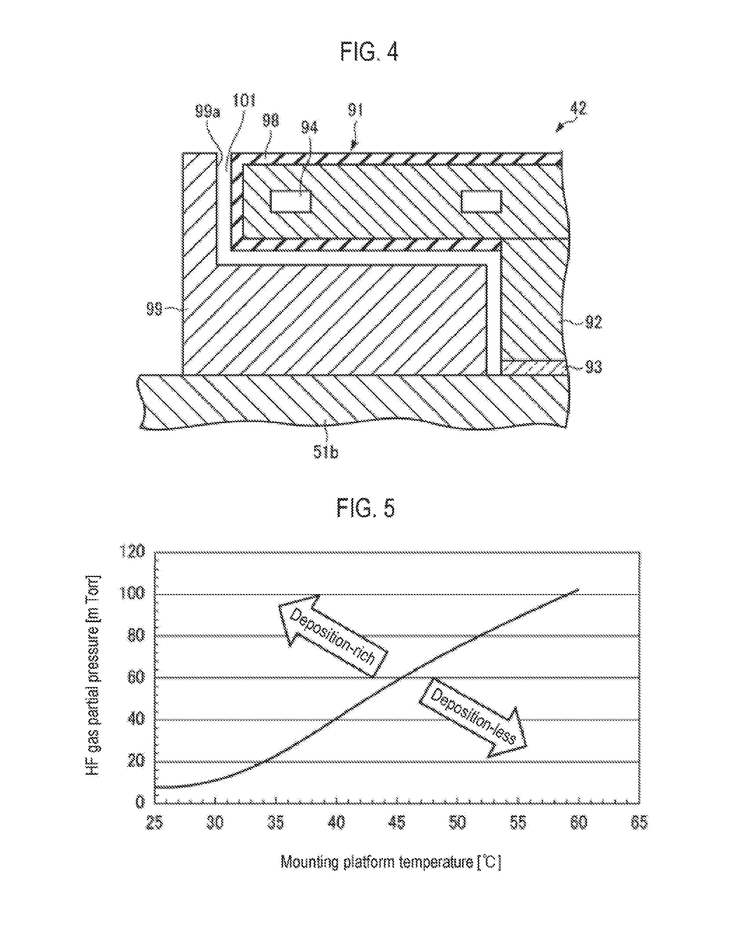

An effect of the partial pressure of the HF gas on the amount of deposits formed on the mounting table 91 was confirmed by the following method. Specifically, when the partial pressure of the HF gas is increased as a function of the temperature of the mounting table 9, a region having an etching rate higher than a threshold value corresponding to a saturation point of the etching rate is defined as a “deposit-rich” region, and a region having an etching rate lower than the threshold value is defined as a “deposit-less” region. In this way, as shown in FIG. 5, a border line between the “deposit-rich” region and the “deposit-less” region was obtained while changing the partial pressure of the HF gas and the temperature. As a result, it was found that a region having a higher HF partial pressure at 50 degrees C. is likely to become the “deposit-rich” region and thus a region having an HF partial pressure of 10 to 80 mTorr at 50 degrees C. is likely to become the “deposit-rich” region. Accordingly, the effects obtained by the formation of the coating layer 98 on the mounting table 91 and by the heating of the lateral and rear surfaces of the mounting table 91 using the heating block 99 are optimized at an HF partial pressure of 10 to 80 mTorr.

<Experimental Results>

Next, experimental results used as the basis of the present disclosure will be described.

(Experimental Result 1)

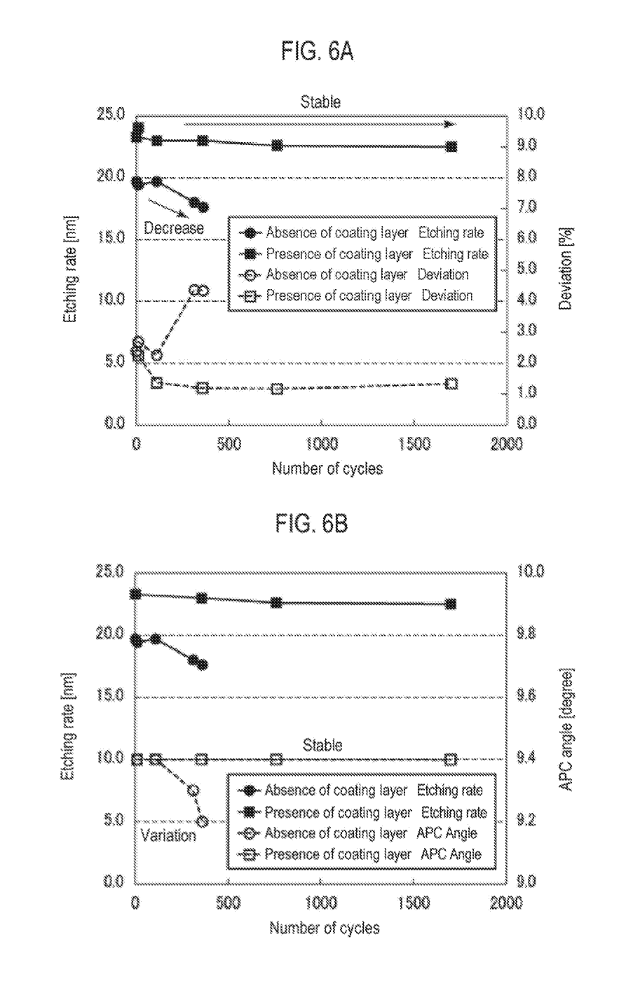

First, in cases where a coating layer is formed on a mounting table made of aluminum and the coating layer is not formed on the mounting table, an etching rate, a deviation thereof and an APC angle when continuously etching a plurality of wafers with the HF gas and the NH₃ gas were obtained as a function of the number of cycles (the number of wafers). The coating layer was formed of an FCH-based resin. FIG. 6A is a view depicting a relationship between the number of cycles, the etching rate, and deviation thereof, and FIG. 6B is a view depicting a relationship between the number of cycles, the etching rate, and the APC angle.

As shown in FIGS. 6A and 6B, in the absence of the coating layer on the mounting table, as the number of cycles is increased to 200 or more, the etching rate was decreased, the deviation of the etching rate was increased and the APC angle is reduced. On the contrary, in the presence of the coating layer on the mounting table, the etching rate and deviation thereof were stabilized even after 1500 cycles, and the APC angle was also stabilized. The reason for this is as follows. In the absence of the coating layer on the mounting table, a large amount of deposits were generated on the mounting table so that the etching gas adhered to the deposits, which reduces the etching rate and also the APC angle. On the contrary, in the presence of the coating layer on the mounting table, the coating layer makes it difficult to generate deposits on the mounting table, which suppresses a decrease in the etching rate or an increase in deviation thereof, and also stabilizes the APC angle.

(Experimental Result 2)

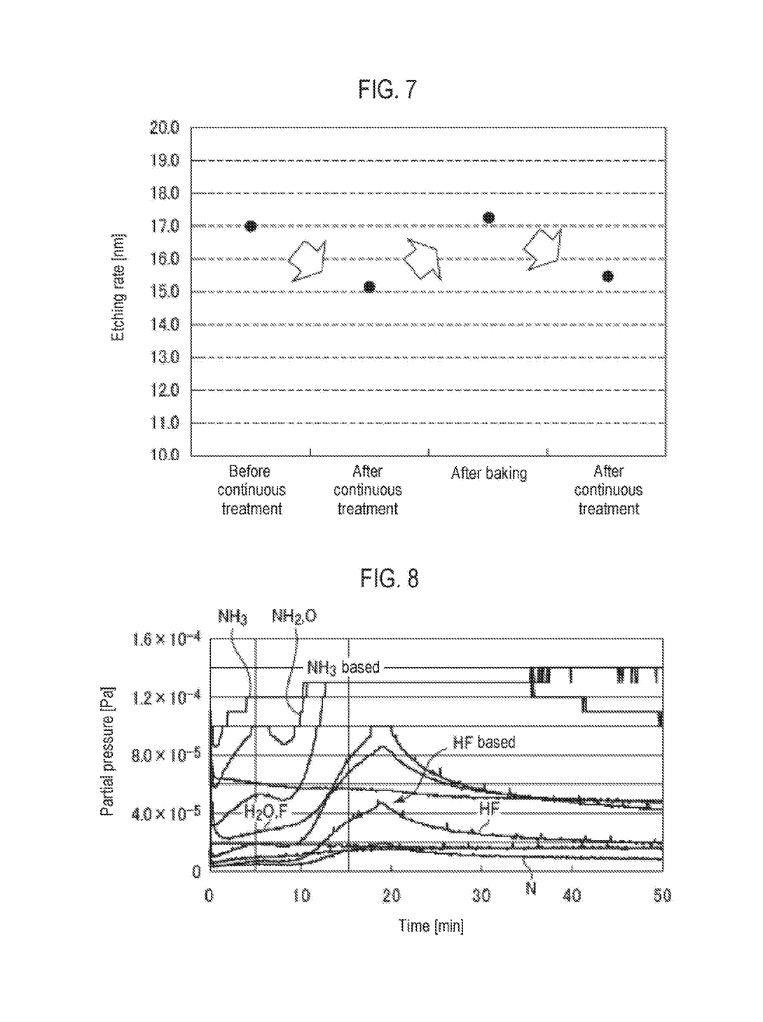

This experiment was performed using a mounting table not including a coating layer. A temperature of a mounting surface of the mounting table is maintained at a low temperature (10 to 40 degrees C.). Under this situation, a first wafer etching rate obtained when an etching treatment is initially performed, a second wafer etching rate obtained after the etching treatment was continuously performed using the HF gas and the NH₃ gas, a third wafer etching rate obtained after a baking treatment was performed at 80 to 100 degrees C., and a fourth wafer etching rate obtained after the continuous etching treatment was further performed, were obtained. Results of this experiment are shown in FIG. 7. As shown in FIG. 7, although the second wafer etching rate obtained after the continuous etching treatment was performed using the HF gas and the NH₃ gas was lower than the first wafer etching rate. The reason for this is that deposits adhere to the mounting table, which results in a decrease in etching rate. Thereafter, the second wafer etching rate was returned to a level of the first wafer etching rate by the baking treatment. The reason for this is that the deposits were sublimated by the baking treatment.

(Experimental Result 3)

After deposits were generated on the mounting table by the etching treatment using the HF gas and the NH₃ gas, materials sublimated upon performing the baking treatment at 80 degrees C. were analyzed using a residual gas analyzer (RGA). Analysis results are shown in FIG. 8. As shown in FIG. 8, an NH₃-based gas and an HF-based gas were detected. It was expected that components of these gases were NH₄F and (NH₄)₂SiF₆.

(Experimental Result 4)

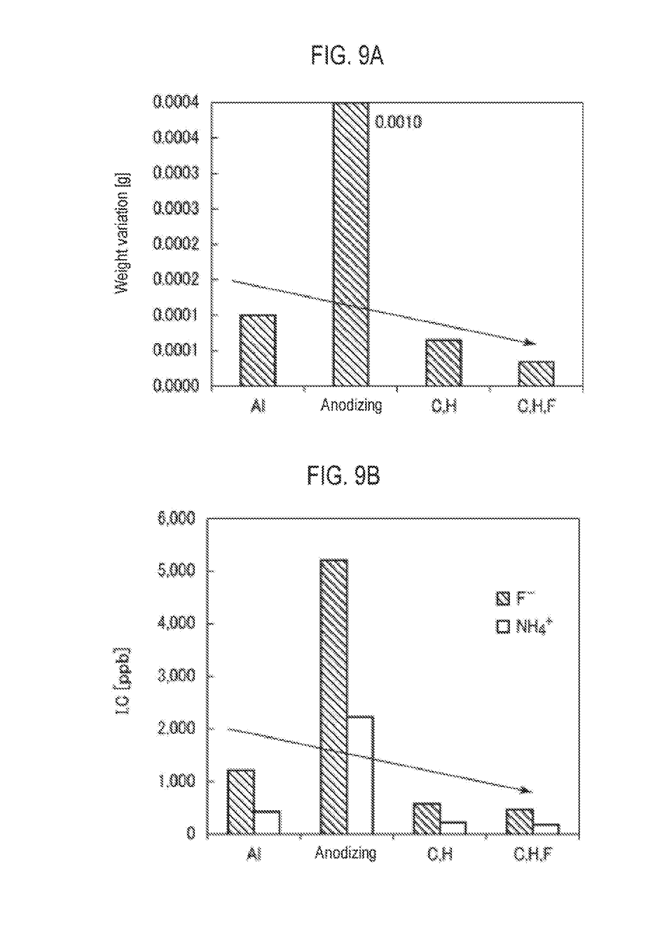

A mounting table formed of aluminum alone, a mounting table formed of aluminum whose surface is anodized, a mounting table having a CH-based coating layer formed thereon, and a mounting table having a CHF-based coating layer formed thereon were prepared, and an etching treatment was performed with HF gas and NH₃ gas. Thereafter, an amount of deposits was obtained through a weight measurement and an ion chromatography. Results are shown in FIGS. 9A and 9B. In FIG. 9B, F⁻ ion and NH⁴⁺ion are shown. As shown in these drawings, each of the mounting tables having respectively the CH-based coating layer and the CHF-based coating layer formed thereon exhibited water repellency and had a smooth surface so that an effect of suppressing generation of deposits is high. Particularly, the CHF-based coating layer provides higher effects than the other coating layers. The anodized surface has high roughness, which causes a large amount of deposits.

<Other Applications of the Present Disclosure>

The present disclosure is not limited to the above embodiments and may be modified in various ways. As an example, although in the above embodiments, the silicon oxide film has been described to be etched using the HF gas and the NH₃ gas as the etching gas, the present disclosure is not limited thereto. In some embodiments, a silicon-containing film may be etched using an etching gas containing fluorine, hydrogen and nitrogen to generate an ammonium fluorosilicate as an etching by-product.

Furthermore, the devices according to the above embodiments have been presented by way of example only. Indeed, the etching method according to the present disclosure may be implemented by various devices having different configurations. Furthermore, while the semiconductor wafer has been described to be used as the target substrate, the present disclosure is not limited thereto. In some embodiments, the target substrate may be other substrates such as a flat panel display (FPD) substrate represented by a liquid crystal display (LCD) substrate, a ceramic substrate, and the like.

### EXPLANATION OF REFERENCE NUMERALS

1: Processing system, 2: Loading/unloading part, 3: Load lock chamber, 4: Heating device, 5: Etching device, 6: Control part, 11: First wafer transfer mechanism, 17: Second wafer transfer mechanism, 40: Chamber, 42: Substrate mounting mechanism, 43: Gas supply mechanism, 44: Exhaust mechanism, 91: Mounting table, 92: Support member, 94: Temperature adjustment medium channel, 95: Temperature adjustment medium circulation mechanism, 98: Coating layer, 99: Heating block, 101: Gap, W: Semiconductor wafer

1. An etching device for etching a silicon-containing film formed on a substrate using an etching gas containing fluorine, hydrogen and nitrogen to generate an ammonium fluorosilicate as a by-product, the etching device comprising:
a chamber configured to accommodate the substrate having the silicon-containing film formed thereon;
a substrate mounting mechanism disposed within the chamber;
a gas supply mechanism configured to supply the etching gas containing fluorine, hydrogen and nitrogen into the chamber; and
an exhaust mechanism configured to exhaust an interior of the chamber,
wherein the substrate mounting mechanism includes:
a mounting table having a mounting surface on which the substrate is mounted,
a temperature adjustment mechanism configured to adjust a temperature of the mounting surface of the mounting table to 50 degrees C. or less; and
a heating member configured to heat at least a portion of surfaces other than the mounting surface in the mounting table to a temperature of 60 to 100 degrees C., and
wherein a coating layer of a resin material is formed at least on the mounting surface of the mounting table.

2. The etching device of claim 1, wherein the etching gas includes an HF gas and an NH₃ gas, and the silicon-containing film is a silicon oxide film.

3. The etching device of claim 1, wherein the coating layer has a contact angle of 75 degrees or more and a surface roughness Ra of 1.9 μm or less.

4. The etching device of claim 3, wherein the coating layer is formed of an FCH-based resin consisting of F, C and H or a CH-based resin consisting of C and H.

5. The etching device of claim 1, further comprising:
a heater configured to heat a wall portion of the chamber,
wherein the heating member heats the surfaces other than the mounting surface in the mounting table using heat that is radiated from the wall portion of the chamber heated by the heater.

6. The etching device of claim 1, wherein the temperature adjustment mechanism adjusts the temperature by circulating a temperature adjustment medium through the mounting table.

7. The etching device of claim 1, wherein a gap is formed between the mounting table and the heating member to act as an exhaust channel.

8. An etching method for etching a silicon-containing film formed on a substrate using an etching gas containing fluorine, hydrogen and nitrogen, to generate an ammonium fluorosilicate as a by-product, the etching method comprising:
installing a mounting table within a chamber, the mounting table including a coating layer of a resin material formed at least on a mounting surface thereof on which the substrate is mounted;
mounting the substrate having the silicon-containing film formed thereon on the mounting surface of the mounting table;
adjusting a temperature of the mounting surface of the mounting table to 50 degrees C. or less;
heating at least a portion of surfaces other than the mounting surface in the mounting table to a temperature of 60 to 100 degrees C.; and
supplying the etching gas containing fluorine, hydrogen and nitrogen into the chamber to etch the silicon-containing film.

9. The etching method of claim 8, wherein the etching gas includes an HF gas and an NH₃ gas, and the silicon-containing film is a silicon oxide film.

10. The etching method of claim 9, wherein a partial pressure of the HF gas at the time of etching falls within a range from 10 to 80 mTorr.

11. The etching method of claim 8, wherein the coating layer has a contact angle of 75 degrees or more and a surface roughness Ra of 1.9 μm or less.

12. The etching method of claim 11, wherein the coating layer is formed of an FCH-based resin consisting of F, C and H or a CH-based resin consisting of C and H.

13. A substrate mounting mechanism for mounting a substrate having a silicon-containing film formed thereon within an etching device which etches the silicon-containing film formed on the substrate using an etching gas containing fluorine, hydrogen and nitrogen to generate an ammonium fluorosilicate as a by-product, the substrate mounting mechanism comprising:
a mounting table having a mounting surface on which the substrate is mounted;
a temperature adjustment mechanism configured to adjust a temperature of the mounting surface of the mounting table to 50 degrees C. or less; and
a heating member configured to heat at least a portion of surfaces other than the mounting surface in the mounting table to a temperature of 60 to 100 degrees C.,
wherein a coating layer of a resin material is formed at least on the mounting surface of the mounting table.

14. The substrate mounting mechanism of claim 13, wherein the etching gas includes an HF gas and an NH₃ gas, and the silicon-containing film is a silicon oxide film.

15. The substrate mounting mechanism of claim 13, wherein the coating layer has a contact angle of 75 degrees or more and a surface roughness Ra of 1.9 μm or less.

16. The substrate mounting mechanism of claim 15, wherein the coating layer is formed of an FCH-based resin consisting of F, C and H or a CH-based resin consisting of C and H.

17. The substrate mounting mechanism of claim 13, wherein a wall portion of the chamber is heated by a heater, and the heating member heats the surfaces other than the mounting surface in the mounting table using heat that is radiated from the wall portion of the chamber heated by the heater.

18. The substrate mounting mechanism of claim 13, wherein the temperature adjustment mechanism adjusts the temperature by circulating a temperature adjustment medium through the mounting table.

19. The substrate mounting mechanism of claim 13, wherein a gap is formed between the mounting table and the heating member to act as an exhaust channel.
